(19) United States
(12) Patent Application Publication
(10) Pub. No.: US 2013/0076206 A1
(43) Pub. Date: Mar. 28, 2013

(54) TOUCH PAD CONTROLLER

(71) Applicants: Armand Rosenberg, Rehovot (IL); Avichai Friedman, Tel Aviv (IL)

(72) Inventors: Armand Rosenberg, Rehovot (IL); Avichai Friedman, Tel Aviv (IL)

(73) Assignee: BARAN ADVANCED TECHNOLOGIES (1986) LTD., (IL)

(21) Appl. No.: 13/702,805

(22) PCT Filed: Jun. 7, 2010
(86) PCT No.: PCT/IL2010/000449

§ 371 Date: Dec. 7, 2012

(51) Int. Cl. H01L 41/113

(52) U.S. Cl. CPC H01L 41/1132
USPC 310/319

(57) ABSTRACT

A system for controlling electrical appliances comprises a) a touch plate having an inner surface and an outer surface, which is accessible to a user; b) a piezoelectric module coupled with said inner surface of said touch plate and suitable to generate electric signals when deformed by pressure; c) a microcontroller connected to said piezoelectric module, said microcontroller being configured to analyze electrical signals generated by said piezoelectric module, to determine; d) circuitry coupled with said microcontroller, for receiving said control signals and for transmitting output signals to said electrical appliance; and e) a feedback module connected to said microcontroller, suitable to provide to a user feedback related to signals generated by said piezoelectric module.

### FIELD OF THE INVENTION

The present invention relates to electronic controllers. More particularly, the invention relates to piezoelectric controllers useful for controlling electrical appliances.

### BACKGROUND OF THE INVENTION

Traditional controllers are operated by users via mechanical or electrical actuators, such as knobs, buttons, or sliders. Traditional interfaces enable controlling or adjusting various properties of the electrical appliance associated with it, but moving parts present the drawback that they are often easily worn out from use over time. Even in controllers that are covered (e.g., electrical push-buttons) for protecting the inner electrical components from corrosive or otherwise damaging elements, environmental conditions such as thermal influences and moisture affect their electrical components over time.

In recent years touch panels have replaced the traditional mechanical and electrical interfaces in many applications. Touch panels are suitable for a variety of applications where the display device itself may also be used for system control or data entry, and conventional touch panels include many types, which are generally classified according to the methodology of the input, e.g., resistive, capacitive, surface wave, infrared, and strain gauge. Each of these generates a stimulus that registers as a touch event.

Resistive systems register a touch event whenever two resistive layers make contact, such that the stimulus may be any solid object, e.g., a human finger or a pencil eraser. In capacitive systems, a human finger near the intersection of two electrodes modifies the mutual capacitance between them, since a finger has very different dielectric properties than air. When a user touches the screen, some of the charge is transferred to the user, and creates a potential difference on the screen. The surface wave system, operating like the resistive system but using ultrasonic waves that pass over the touch panel, allows a touch event to be registered using any object that can effectively disturb the waves.

Each of the abovementioned designs has distinct disadvantages. For example, resistive systems easily suffer from damages in their polyester surface. Additionally, resistive systems are known for their lower endurance (limited amount of touches). A capacitive system, on the other hand, must have a conductive input, which is most typically supplied by a user's finger, therefore, it is difficult to select small items. Capacitive systems are well known for inducing electrical fields in nearby radios. Therefore, capacitive systems are not appropriate for controlling electrically sensitive devices. When installing capacitive systems one should also consider the compound of the controller housing, conductive materials in close proximity to the capacitors may highly affect the controller functionality. Capacitive systems also suffer from high cost, software dependency, input inaccuracy, and limits on using a stylus or a gloved finger to make inputs.

Compared to resistive and capacitive technologies, surface wave systems provide high resolution. However, they must be touched by finger, gloved hand, or soft-tip stylus. In addition the touch panel is not completely sealable, thus, it is affected by dirt, dust, and moisture. Infrared touch technology is very expensive.

To help address these problems, touch panels based on piezoelectric elements have developed. Touch panels based on piezoelectric technology allow controlling a system via a touch plate. The application of tactile pressure onto the outer surface of the touch plate causes a slight deformation in a piezoelectric element attached to it. In response to its slight deformation, the piezoelectric element generates an electrical signal.

Piezoelectric controllers mimic the traditional mechanical controllers and allow a user to adjust system properties in a linear manner, where the final value of the controller output is determined based on the total displacement of the control from an initial origin or reference point. However, in some situations the linear adjustment methods are inadequate or impractical. For example, a communication system which operates over a frequency bandwidth of 1 MHz, with channels spaced by 1 KHz has 1000 possible channel increments across the relevant frequency band. Linear adjustment mechanisms may require a significant amount of time to traverse the wide range of values and locate the desired channel. Furthermore, in order to accommodate a large range of values, linear adjustment mechanisms, such as a traditional scrollbar, require a substantial amount of area on the display for presenting the full spectrum supported by the controller.

Other piezoelectric controllers known in the art provide limited user operation by displaying minimum controlling range or by minimizing the size of icons (e.g., range bars, numbers) in order to increase the number of simultaneously displayed icons. However, reducing icon size renders the operation by a user more difficult and tends to contribute to inputting errors. In particular, icons may become too small for a consistent and accurate manipulation by a human finger, so that the system experiences difficulty in correctly recognizing a particular touch event. Currently, touch panel manufacturers report a 1.5% error rate in command recognition over a touch screen.

A need therefore exists in the art for a system that provides touch panels based on piezoelectric elements, which incorporate the important benefits of prior art controlling systems while addressing the concerns noted above, which allows a continuous change of the controlled parameter.

It is therefore an object of the present invention to provide a system and method for the continuous control of an electrical appliance utilizing a touch pad based on piezoelectric technology.

Another object of the present invention is to provide a reliable system protected from corrosive or other environmental damaging elements.

Yet another object of the present invention is to provide a system and method adapted to control sensitive devices that can be installed in close proximity to all kinds of equipment without generating disturbances.

An additional object of the present invention is to provide a system and method adapted to be easily retrofitted in existing electrical appliances.

Other objects and advantages of the invention will become apparent as the description proceeds.

### SUMMARY OF THE INVENTION

In one aspect the invention is directed to a system for controlling electrical appliances, comprising:
(a) A touch plate having an inner surface and an outer surface, which is accessible to a user;
(b) A piezoelectric module coupled with said inner surface of said touch plate and suitable to generate electric signals when deformed by pressure;
(c) A microcontroller connected to said piezoelectric module, said microcontroller being configured to analyze electrical signals generated by said piezoelectric module, to determine;
(d) Circuitry coupled with said microcontroller, for receiving said control signals and for transmitting output signals to said electrical appliance; and
(e) A feedback module connected to said microcontroller, suitable to provide to a user feedback related to signals generated by said piezoelectric module.

The electrical appliance is selected from the group consisting of lights, air conditions, stoves, amplifiers, fans, blenders, industrial equipment and machinery, volume modules and speakers.

The piezoelectric module is configured to undergo deformation as a result of a tactile pressure selected from the group consisting of sliding, tapping, continuous touch and sequence of taps.

The piezoelectric module comprises one or more piezoelectric sensors connected to the microcontroller.

In one embodiment of the invention the microcontroller is configured to analyze the electrical signals generated by the piezoelectric module for recognizing one or more of the location of the deformation, the speed and direction of the movement and the intensity of the touch.

The microcontroller is programmable to support one or more of linear control, dynamic control, parent control, tap control, or a combination thereof.

In one embodiment of the invention the circuitry further comprises a power supply which is fed from an internal voltage fall.

In one embodiment of the invention the circuitry further comprises an AC/DC switch adapted to adjust an input signal according to control signals, wherein the input signal comes from an external power grid and provided to the electrical appliance coupled to said controller.

The feedback module provides acoustic feedback, or visual feedback, or a combination of both.

The invention further encompasses a method for controlling electrical appliance, comprising:
i) physically connecting a piezoelectric-based controller to the electrical appliance;
ii) providing a touch plate adapted for tactile input to the controller;
iii) analyzing the tactile input and generating control signals related to it;
iv) adjusting the power supplied to the electrical appliance according to the control signals; and
v) generating feedback to a user according to the power supplied and/or to the tactile input.

Adjusting the power supplied to the electrical appliance is performed by switching power on, or switching power off, or increasing power, or decreasing power.

The electrical appliance is selected from the group consisting of lights, air conditions, stoves, amplifiers, fans, blenders, industrial equipment and machinery, volume modules and speakers.

### BRIEF DESCRIPTION OF THE DRAWINGS

The above and other characteristics and advantages of the invention will be better understood through the following illustrative and non-limitative detailed description of embodiments thereof, with reference to the appended drawings, wherein:

FIG. 1 schematically illustrates a block diagram of one exemplary embodiment of the present invention;

FIG. 2 illustrates a piezoelectric-based control module device of one exemplary embodiment of the present invention; and

FIG. 3 illustrates a piezoelectric slider exemplary embodiment of the present invention;

### DETAILED DESCRIPTION OF THE INVENTION

In the following description, for the purpose of illustration, numerous specific details are provided. As will be apparent to the skilled person, however, the invention is not limited to such specific details and the skilled person will be able to devise alternative arrangements.

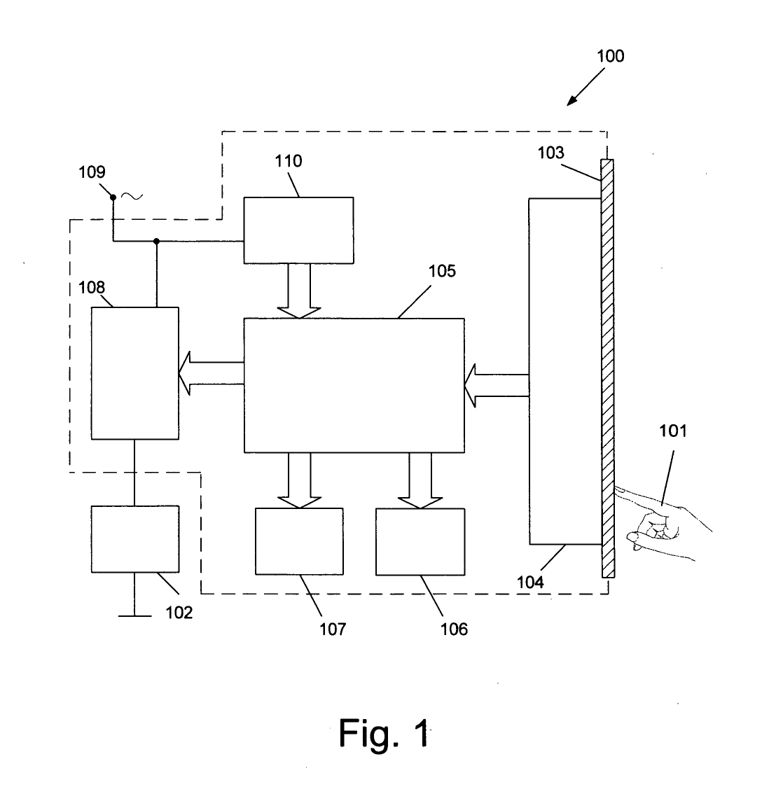

FIG. 1 schematically illustrates a block diagram of one exemplary embodiment of the present invention. A user's hand 101 is seen, which uses a device according to one embodiment of the invention for adjusting the current supplied to a load 102 (e.g., light, AC, stove, sound amplifier, speakers, fan, volume module and other industrial equipment and machinery) connected to the controller 100. The controller utilizes an input interface that includes a top layer 103 in the form of a plate. The top layer is accessible to the user. The bottom layer 104 of the input interface includes a piezoelectric sensors array. The piezoelectric array is attached to the plate such that when the user touches the plate with his finger, the piezoelectric array senses it and sends signals to a microcontroller 105. Touching the top plate causes a slight deformation that is detected by the underlining piezoelectric sensors array.

The piezoelectric sensor array is connected to the microcontroller which analyzes the position of the deformation and the speed and direction of the movement. The microcontroller adjusts the controller output signal (from “off” state to maximum power) according to the user input. Controlling the output signal according to the parameters of the movement (e.g., speed, direction and intensity) is referred hereinafter as “dynamic control”. “Linear control” refers to a method in which the controller is adapted only to changing the output signal linearly according to the touch, regardless of the parameters of the movement.

In the embodiment of FIG. 1 the controller provides visual and acoustic feedback in response to its input and output. A buzzer module 106 is responsible for generating the acoustic feedback according to input from the microcontroller. The acoustic feedback according to this embodiment is provided in the form of audio clicks in response to user touch and changes in the output signal to the load. For example, if a user generates a fast movement over the touch plate, a large amount of fast clicks is heard (mimicking the sound generated while quickly turning a mechanical dial). Such acoustic feedback indicates that the fast movement generated a large change in the controller output signal to the load (e.g., in a controller utilized as a light dimmer, a fast, even if short slide over the plate causes the light to be considerably dimmed). In the dynamic control mode the microcontroller is adapted to analyze the velocity of the touching movement and to change the output signal accordingly. Considering the velocity allows controlling large-scale systems without the need for large display size. For example, by fast sliding over the touch plate one can easily reach from 0 to 100 on an 0 to 100 scale, while slow sliding will cause a change of few units on the same scale. Unlike linear adjustment a significant amount of time is saved while setting the desired frequency.

A display module 107 is responsible for receiving signals from the microcontroller and for generating a resulting visual feedback. The current state of the controller is displayed by numbers, graphs, LEDs or any other method that is customary for visual feedback. According to one embodiment the visual feedback is provided by illuminating a transparent bar. Like for the acoustic feedback, the visual feedback is adapted to the features of the touch, such as, velocity of movement and intensity of touch.

Adapting the signal provided to the load and to the feedback modules is done by the microcontroller. The microcontroller receives the signals from the piezoelectric sensor array and analyzes it. The microcontroller extracts the features (such as velocity and direction) of the touch/slide and provides a controlling signal to the AC/DC switch 108 and to the feedback modules 106 and 107. For example, in the 0 to 100 scaled touch plate mentioned above, a fast slide in the ‘up’ direction (e.g. above 1 [m/s]) causes the microcontroller to set a high value at the controlling signals immediately. Accordingly, a slow slide (e.g. below 0.1 [m/s]) in the ‘down’ direction changes the controlling signal to reduce only few units on the 0 to 100 scale.

In this example the AC/DC switch is connected to the national power grid at point 109 and to the load at another point. Considering the signals from the microcontroller, the AC/DC switch adapts the signal coming from the power grid to transmit an appropriate signal to the load. A power supply 110 is also provided in this embodiment. The power supply is fed from an internal voltage fall and provides the voltage to the microcontroller and inner circuits. Generally, the controller is connected in the same way as traditional controllers. The traditional connectivity provides easy retrofitting in existing electrical appliances which makes the present invention attractive for the Do It Yourself market and highly cost-effective.

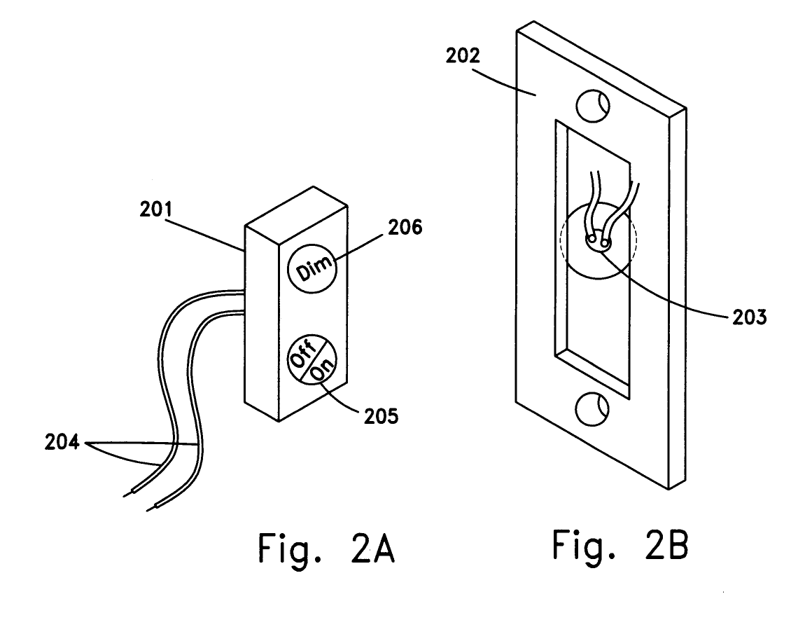

FIG. 2 illustrates a piezoelectric-based control module device of one exemplary embodiment of the present invention. According to this embodiment the system is housed as a modular independent unit 201 for retrofitting into existing light control devices. After disconnecting the existing mechanical dimmer module, a dimmer mounting plate 202 remains connected to the wall covering the grid power supply cable 203 (phase-in and phase-out). Retrofitting the piezoelectric control module is done by simply connecting both wires 204 (phase-in and phase-out) of the control module to the power grid supply cable. The control module is adapted to consume 11-8 negligible energy while not activated.

The housing of the piezoelectric control module 201 in this embodiment comprises two control interfaces. The lower control interface 205 is a piezoelectric-based touch button. According to one embodiment of the invention the touch button mimics a traditional on-off switch. Touch buttons can be implemented using one or two piezoelectric sensors. One sensor embodiment means that each touch alternately turns the light on and off. Two sensors embodiment allocates one sensor as on and the second as off. The lower control interface 205 is an exemplary two sensors touch button. According to one embodiment the on-off switch is adapted to gradually change the lamp illumination level (i.e. gradual lamp illumination when the switch is activated “on” and a gradual light dimming when the switch is activated “off”).

The upper part of the control module comprises a touch dimmer 206 which mimics the traditional round dimmer. By continuously pushing the touch dimmer, the output power signal changes. According to one embodiment of the invention the microcontroller considers the last change so that each touch generates the opposite action. By utilizing the piezoelectric technology in such way, one small button-like surface is used both as an on-off button and as a dimmer. Each short touch changes the output power signal from “on” to “off” and vice versa. Continuous touches alternately dim and brighten the light.

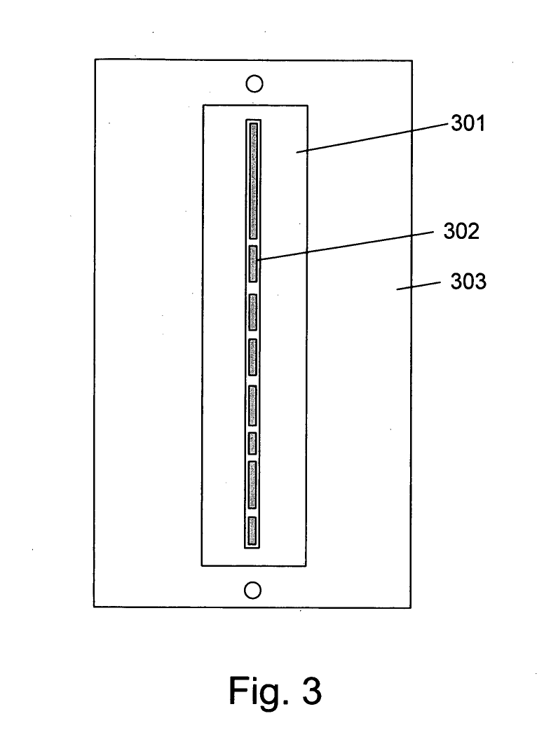

FIG. 3 illustrates a piezoelectric slider exemplary embodiment of the present invention. According to this embodiment there is no need for rotating a dimmer by twisting the wrist unnaturally. The piezoelectric slider allows controlling a dimmer by sliding a finger or any other object over it. The slider of this embodiment achieves the smooth design of the touch plate 301 without any moving elements. A visual feedback is provided in the form of a led light bar 302 indicating the intensity of the signal provided to the load (light) and, as a side advantage, helping to locate the dimmer in the dark. The slider touch plate 301 and the mounting plate 303 in this embodiment are made of metal to achieve strong, reliable, and fashionable design. The slider provides fast and efficient controlling by sensing parameters such as touching speed. The control module senses the speed of the touch (e.g., by calculating time elapsed between the activation of adjacent piezoelectric elements in the sensor array) and dims the light operatively coupled to it accordingly.

According to one embodiment, the piezoelectric controller of the type described above is hermetically sealed to protect against harmful environmental conditions (e.g., thermal influences and moisture). Specifically, because the piezoelectric controller includes no moving mechanical parts, the interior cavity of the housing for the piezoelectric controller is filled with a potting compound, such as silicon, to protect the electrical components of the controller from corrosive or other damaging elements, which is highly desirable for system robustness. Another advantage of the piezoelectric controller is the fact that no electrical field is created during its activation. Therefore, it is adapted to control sensitive devices and installed in close proximity to all kinds of compounds.

The piezoelectric controller of the present invention is adapted to support several advanced features. In one embodiment the controller provides a multi-channel signal, i.e., the output power is transferred to several loads. The microcontroller integrated in the controller is programmable to support controlling methods such as linear control, dynamic control, parent control and tap control. Parent control offers means to manage which options are accessible to a user. If parent control is applied, a unique touch sequence is prompted; inserting the correct sequence allows adjusting the parent control settings. The parent control default setting is “OFF” which means that the controller allows adjusting all the functions supported (e.g., dim, bright, on, off, linear, dynamic). Changing the parent control settings to be more secured, blocks some of the functions originally supported by the controller. Tap control allows programming the microcontroller to identify specific tapping sequences (characterized by tap duration and spacing) and to adjust the output signal accordingly (e.g., identifying a unique Morse code taps causes to lock the controller such that further input is ignored).

While some embodiments of the invention have been described by way of illustration, it will be apparent that the invention can be carried out with many modifications, variations and adaptations, and with the use of numerous equivalents or alternative solutions that are within the scope of persons skilled in the art, without departing from the spirit of the invention or exceeding the scope of the claims.

1. A system for providing non-linear control over electrical appliances, comprising:
(a) a touch plate having an inner surface and an outer surface, which is accessible to a user;
(b) a piezoelectric sensor array coupled with said inner surface of said touch plate and suitable to generate electric signals when deformed by pressure;
(c) a microcontroller connected to said piezoelectric module, said microcontroller being configured to analyze electrical signals generated by said piezoelectric module, to determine control signals therefrom;
(d) circuitry coupled with said microcontroller, for receiving said control signals and for transmitting output signals to said electrical appliance; and
(e) a feedback module connected to said microcontroller, suitable to provide to a user feedback related to signals generated by said piezoelectric module.

2. A controller according to claim 1, wherein the electrical appliance is selected from the group consisting of lights, air conditions, stoves, amplifiers, fans, blenders, industrial equipment and machinery, volume modules and speakers.

3. A controller according to claim 1, wherein the piezoelectric module is configured to undergo deformation as a result of a tactile pressure selected from the group consisting of sliding, tapping, continuous touch and sequence of taps.

4. A controller according to claim 1, wherein the piezoelectric module comprises one or more piezoelectric sensors connected to the microcontroller.

5. A controller according to claim 1, wherein the microcontroller is configured to analyze the electrical signals generated by the piezoelectric module for recognizing one or more of the location of the deformation, the speed and direction of the movement and the intensity of the touch.

6. A controller according to claim 1, wherein the microcontroller is programmable to support one or more of linear control, dynamic control, parent control, tap control, or a combination thereof.

7. A controller according to claim 1, wherein the circuitry further comprises a power supply which is fed from an internal voltage fall.

8. A controller according to claim 1, wherein the circuitry further comprises an AC/DC switch adapted to adjust an input signal according to control signals, wherein the input signal comes from an external power grid and provided to the electrical appliance coupled to said controller.

9. A controller according to claim 1, wherein the feedback module provides acoustic feedback, or visual feedback, or a combination of both.

10. A method for controlling electrical appliance, comprising:
i) physically connecting a piezoelectric-based controller to the electrical appliance;
ii) providing a touch plate adapted for tactile input to the controller;
iii) analyzing the tactile input and generating control signals related to it;
iv) adjusting the power supplied to the electrical appliance according to the control signals; and
v) generating feedback to a user according to the power supplied and/or to the tactile input.

11. The method of claim 10, wherein adjusting the power supplied to the electrical appliance is performed by switching power on, or switching power off, or increasing power, or decreasing power.

12. The method of claim 10, wherein the electrical appliance is selected from the group consisting of lights, air conditions, stoves, amplifiers, fans, blenders, industrial equipment and machinery, volume modules and speakers.
